(19) United States
(12) Patent Application Publication
(10) Pub. No.: US 2014/0104960 A1
(43) Pub. Date: Apr. 17, 2014

(54) Methods and Apparatus for Designing and Constructing High-Speed Memory Circuits

(71) Applicants: Sundar Iyer, Palo Alto, CA (US); Shang-Tse Chuang, Los Altos, CA (US); Thu Nguyen, Palo Alto, CA (US); Sanjeev Joshi, San Jose, CA (US); Adam Kablanian, Los Altos Hills, CA (US)

(72) Inventors: Sundar Iyer, Palo Alto, CA (US); Shang-Tse Chuang, Los Altos, CA (US); Thu Nguyen, Palo Alto, CA (US); Sanjeev Joshi, San Jose, CA (US); Adam Kablanian, Los Altos Hills, CA (US)

(21) Appl. No.: 13/651,698

(22) Filed: Oct. 15, 2012

(51) Int. Cl. G11C 7/12; G11C 7/10

(52) U.S. Cl. 365/189.05; 365/203

(57) ABSTRACT

Static random access memory (SRAM) circuits are used in most digital integrated circuits to store digital data bits. SRAM memory circuits are generally read by decoding an address, reading from an addressed memory cell using a set of bit lines, outputting data from the read memory cell, and precharging the bit lines for a subsequent memory cycle. To handle memory operations faster, a bit line multiplexing system is proposed. Two sets of bit lines are coupled to each memory cell and each set of bit lines are used for memory operations in alternating memory cycles. During a first memory cycle, a first set of bit lines accesses the memory array while precharging a second set of bit lines. Then during a second memory cycle following the first memory cycle, the first set of bit lines are precharged while the second set of bit lines accesses the memory array to read data.

### RELATED APPLICATIONS

The present application is related to the U.S. patent application entitled “Methods and Apparatus for Designing and Constructing Multi-port Memory Circuits with Voltage Assist” filed on Mar. 15, 2012 having Ser. No. 13/421,704 which is hereby incorporated by reference.

### TECHNICAL FIELD

The present invention relates to the field of digital memory circuits. In particular, but not by way of limitation, the present invention discloses techniques for designing and constructing high-speed digital memory circuits.

### BACKGROUND

Computer system manufacturers are always attempting to increase computing performance in order to provide more features to computer customers. This is true for personal computers, cellular smart phones, videogame consoles, tablet computer systems, and any other type of computing platform. Computer system manufacturers have met this demand by using increasingly powerful computer processors. Initially, computer processor performance was improved by increasing clock speeds and using wider data words (8-bit to 16-bit to 32-bit to 64-bit processors). More recently, computer processor performance has been improved by using architectural innovations such as instruction level parallelism, pipelining, the issuing of multiple instructions per cycle, and multi-core processors.

However, memory system performance improvements have not kept pace with processor performance improvements. Various techniques have been used to improve the performance of memory systems such as increasing clock speeds, using more on-chip cache memory, and using multi-layer cache systems. However, the very same basic memory circuits used over a decade ago are still used within modern memory systems.

Thus, the memory system performance improvements have not been able to keep with the rapid pace of computer processor performance improvements. This has created a problem known as the “processor-memory performance gap” in the computer industry. Modern processors are often unable to reach their full potential since the processors may be limited by the speed at which new data can be fed into the processors. Therefore, it would be desirable to have improved memory circuits that provide raw memory system performance improvements.

### BRIEF DESCRIPTION OF THE DRAWINGS

In the drawings, which are not necessarily drawn to scale, like numerals describe substantially similar components throughout the several views. Like numerals having different letter suffixes represent different instances of substantially similar components. The drawings illustrate generally, by way of example, but not by way of limitation, various embodiments discussed in the present document.

FIG. 1 illustrates a computer system within which a set of instructions, for causing the machine to perform any one or more of the methodologies discussed herein, may be executed.

FIG. 2A illustrates a typical six transistor (6T) SRAM memory cell.

FIG. 2B illustrates the process of reading from a typical 6T SRAM memory cell.

FIG. 2C illustrates a full transistor view of a typical 6T SRAM memory cell.

FIG. 3A illustrates a block diagram of a SRAM memory system containing an array of SRAM bit cell circuits from FIGS. 2A to 2C.

FIG. 3B illustrates the SRAM memory system of FIG. 3A containing additional circuit details.

FIG. 4 illustrates a timing diagram describing the circuit activities that occur in a SRAM memory system that responds to a memory read request within one operating cycle.

FIG. 5 illustrates a circuit diagram of a typical dual port eight transistor (8T) SRAM memory cell circuit.

FIG. 6 illustrates a timing diagram of how the 8T SRAM bit cell circuit of FIG. 5 may be used to implement a high-speed single-port memory system.

FIG. 7A illustrates a dual-port six-transistor (6T) SRAM bit cell that has independent bit lines for accessing the two sides of the memory cell.

FIG. 7B illustrates a block diagram of the dual-port 6T SRAM bit cell of FIG. 7A coupled to sense amplifiers for performing pseudo differential read operations.

### DETAILED DESCRIPTION

The following detailed description includes references to the accompanying drawings, which form a part of the detailed description. The drawings show illustrations in accordance with example embodiments. These embodiments, which are also referred to herein as “examples,” are described in enough detail to enable those skilled in the art to practice the invention. It will be apparent to one skilled in the art that specific details in the example embodiments are not required in order to practice the present invention. For example, although some of the example embodiments are disclosed with reference to static random access memory (SRAM) circuits, the teachings of this disclosure may be used with other types of memory circuits. The example embodiments may be combined, other embodiments may be utilized, or structural, logical and electrical changes may be made without departing from the scope of what is claimed. The following detailed description is, therefore, not to be taken in a limiting sense, and the scope is defined by the appended claims and their equivalents.

In this document, the terms “a” or “an” are used, as is common in patent documents, to include one or more than one. In this document, the term “or” is used to refer to a nonexclusive or, such that “A or B” includes “A but not B,” “B but not A,” and “A and B,” unless otherwise indicated. Furthermore, all publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

Computer Systems

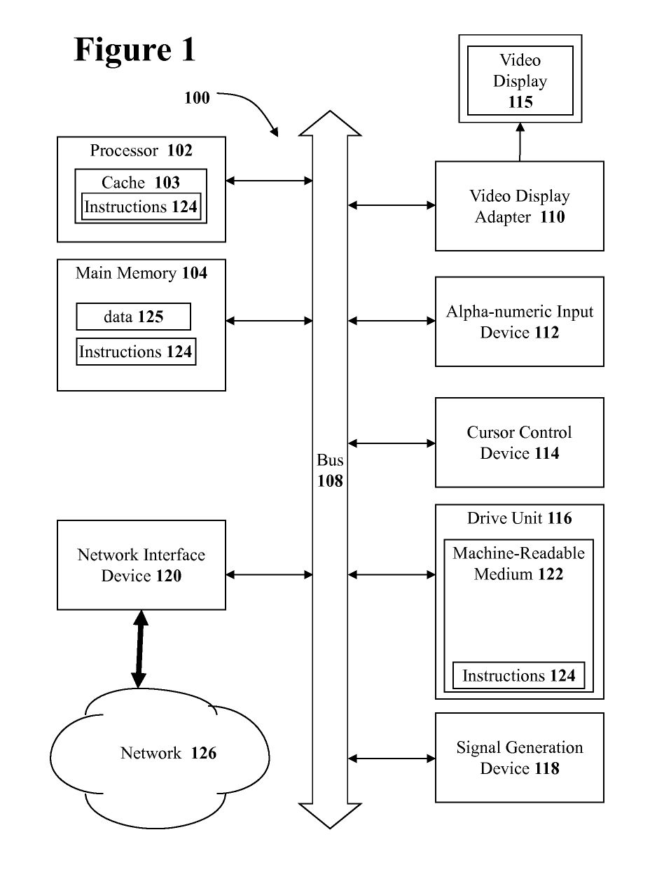

The present disclosure concerns digital memory devices that are often used in computer systems. FIG. 1 illustrates a diagrammatic representation of a machine in the example form of a computer system 100 that may be used to implement portions of the present disclosure. Within computer system 100 of FIG. 1, there are a set of instructions 124 that may be executed for causing the machine to perform any one or more of the methodologies discussed within this document. Furthermore, while only a single computer is illustrated, the term “computer” shall also be taken to include any collection of machines that individually or jointly execute a set (or multiple sets) of instructions to perform any one or more of the methodologies discussed herein.

The example computer system 100 of FIG. 1 includes a processor 102 (e.g., a central processing unit (CPU), a graphics processing unit (GPU) or both) and a main memory 104 and a static memory 106, which communicate with each other via a bus 108. The computer system 100 may further include a video display adapter 110 that drives a video display system 115 such as a Liquid Crystal Display (LCD). The computer system 100 also includes an alphanumeric input device 112 (e.g., a keyboard), a cursor control device 114 (e.g., a mouse or trackball), a disk drive unit 116, a signal generation device 118 (e.g., a speaker) and a network interface device 120. Note that not all of these parts illustrated in FIG. 1 will be present in all embodiments. For example, a computer server system may not have a video display adapter 110 or video display system 115 if that server is controlled through the network interface device 120.

The disk drive unit 116 includes a machine-readable medium 122 on which is stored one or more sets of computer instructions and data structures (e.g., instructions 124 also known as ‘software’) embodying or utilized by any one or more of the methodologies or functions described herein. The instructions 124 may also reside, completely or at least partially, within the main memory 104 and/or within a cache memory 103 associated with the processor 102. The main memory 104 and the cache memory 103 associated with the processor 102 also constitute machine-readable media.

The instructions 124 may further be transmitted or received over a computer network 126 via the network interface device 120. Such transmissions may occur utilizing any one of a number of well-known transfer protocols such as the well-known File Transport Protocol (FTP). While the machine-readable medium 122 is shown in an example embodiment to be a single medium, the term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding or carrying a set of instructions for execution by the machine and that cause the machine to perform any one or more of the methodologies described herein, or that is capable of storing, encoding or carrying data structures utilized by or associated with such a set of instructions. The term “machine-readable medium” shall accordingly be taken to include, but not be limited to, solid-state memories, optical media, and magnetic media.

For the purposes of this specification, the term “module” includes an identifiable portion of code, computational or executable instructions, data, or computational object to achieve a particular function, operation, processing, or procedure. A module need not be implemented in software; a module may be implemented in software, hardware/circuitry, or a combination of software and hardware.

Static Random Access Memory (SRAM) Cell

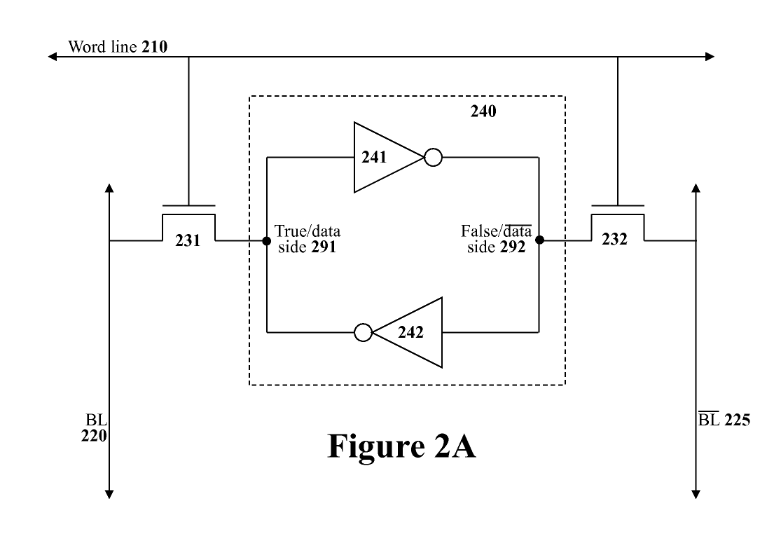

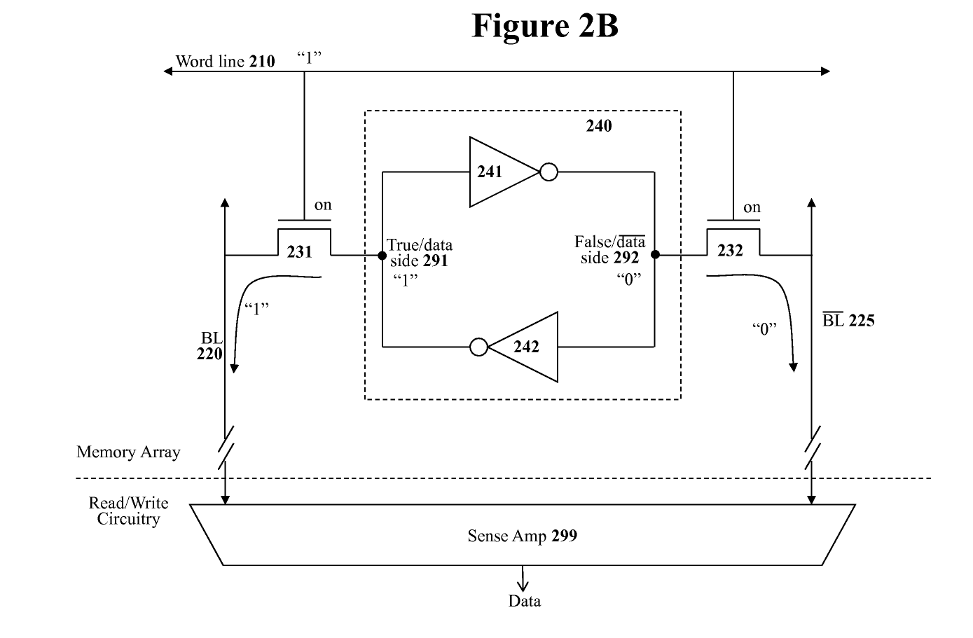

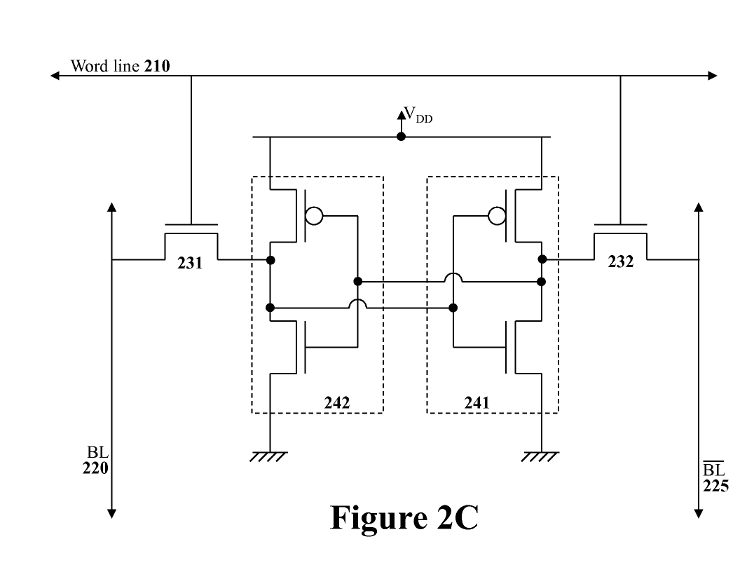

A static random access memory (SRAM) circuit is one type of semiconductor memory circuit that stores a single data bit in a simple memory cell circuit that often consists of a pair of connected inverter circuits. FIG. 2A illustrates a typical static random access memory (SRAM) bit cell circuit 240 comprising a pair of inverters 241 and 242. The inverters 241 and 242 are typically connected in a loop circuit wherein the output of each inverter circuit is coupled to the input of the other inverter circuit. One side of the memory bit cell circuit 240 is referred to as the data or “true” side 291 and represents the stored the data bit value. The other side of the memory cell circuit 240 is often referred to as the data-complement or “false” side 292 and represents the logical inverse of the stored data bit.

A pair of port transistors (231 and 232) is used to write a data bit into the memory bit cell circuit 240 or read a data bit from the memory bit cell circuit 240. A single word line 210 controls the operation of the pair of port transistors (231 and 232). The port transistors 231 and 232 receive data from (for write operations) or drive data on (for read operations) a pair of associated data bit lines: bit line (BL) 220 and bit line complement ( B̅L̅) 225, respectively.

FIG. 2B illustrates reading a “1” data bit (generally represented by a positive voltage value) from the data side 291 and a reading “0” data bit (generally represented by ground) from the data-complement side 292 of the memory bit cell circuit 240 through port transistors 231 and 232, respectively. A differential sense amplifier 299 coupled to the bit lines BL 220 and B̅L̅ 225 determines the value of the data bit stored within SRAM bit cell circuit 240.

FIG. 2C illustrates the SRAM cell of FIG. 2A with the two inverters (241 and 242) replaced with the transistor circuits used to implement the inverters. Each inverter (241 and 242) is implemented with a PMOS transistor and an NMOS transistor. Since there are two transistors for each of the two inverters (241 and 242) and there are two transistors used as port transistors (231 and 232) into the memory cell, the SRAM bit cell of FIG. 2C is commonly known as a six transistor (6T) SRAM bit cell circuit.

SRAM Array Overview

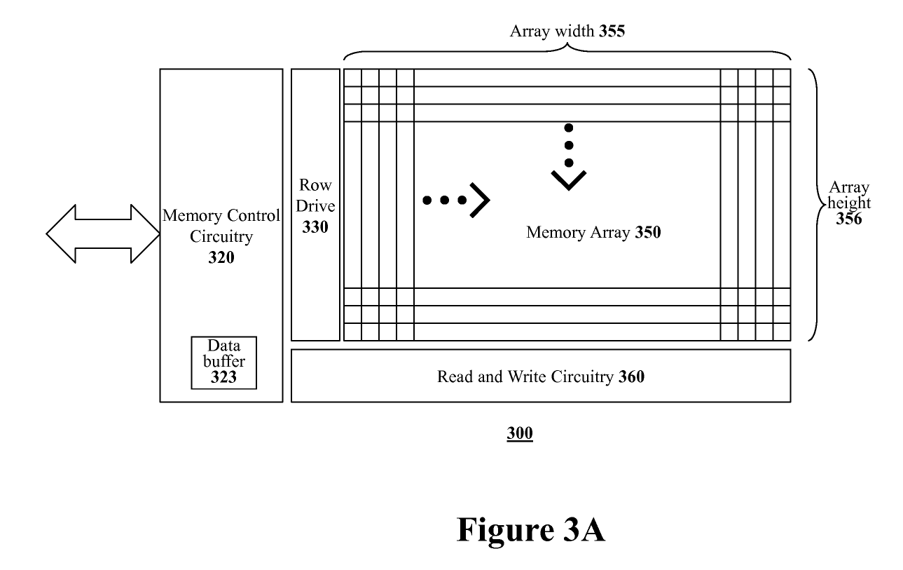

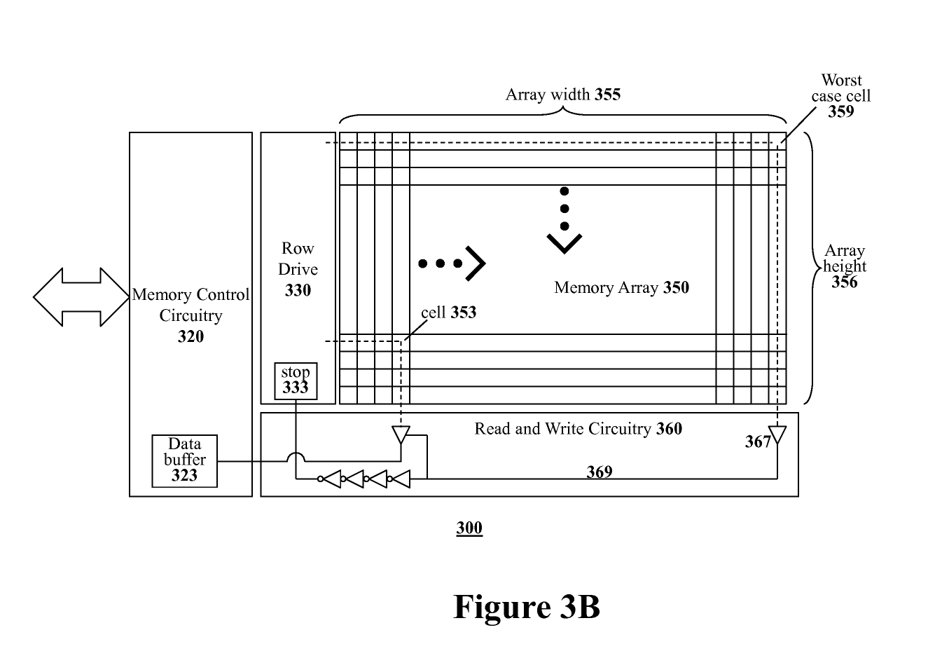

Although the SRAM bit cell circuit of FIGS. 2A to 2C may be used individually, the SRAM bit cell circuit is often used within a two-dimensional array of many individually-addressable SRAM bit cell circuits. FIG. 3A illustrates a block diagram of a SRAM memory system 300 containing a SRAM memory array 350 constructed with many instances of the SRAM bit cell circuit of FIGS. 2A to 2C arranged in a two-dimensional array.

The SRAM memory system 300 of FIG. 3A is controlled by memory control circuitry 320. The memory control circuitry 320 receives a memory access request from an external memory user (not shown) and then acts on the memory access request using row drive circuit 330 and read/write circuitry 360 to access an individual SRAM bit cell circuit within the SRAM array 350. Multiple memory arrays may be combined together in order to access multiple different bits simultaneously.

To access an individual SRAM bit cell circuit within the SRAM memory array 350, the memory control circuitry 320 decodes a received memory address and uses the decoded memory address to activate an associated horizontal word line with row drive circuit 330. The memory control circuitry 320 then instructs the read/write circuitry 360 to read data from or write data onto a specific pair of vertical bit lines into the SRAM array 350. The combination of activating a horizontal word line row with the row drive circuit 330 and read/writing to a vertical bit line column with read/write circuitry 360 accesses a specific individual SRAM bit cell circuit within the memory array 350.

SRAM Array Timing

Several different coordinated circuit actions must take place within the SRAM memory system 300 in order to read a specific addressed memory bit cell within the memory array 350. The total time required to perform all of these coordinated circuit actions determines the operating speed of the SRAM memory system 300.

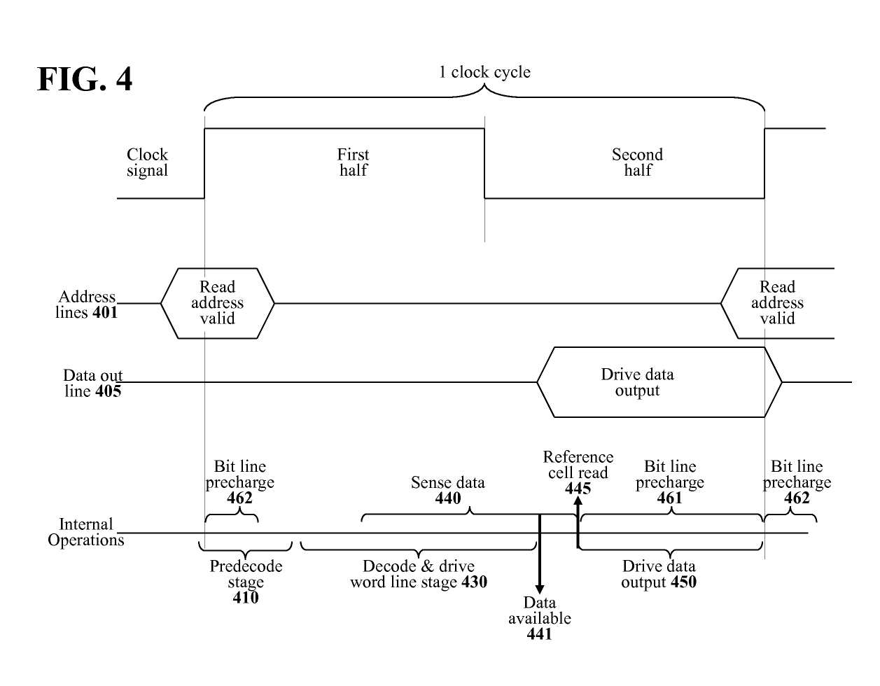

FIG. 4 illustrates a timing diagram that describes the circuit activities that occur in a typical SRAM memory system that responds to a memory read request in one operating cycle. At the start of a memory read operation, the memory system receives a read address on a set of address lines 401 at the beginning of the clock cycle. The read address on the address lines 401 is first acquired and processed by the memory control circuitry 320 during a pre-decode stage 410.

Next, during a decode and drive word line stage 430, the received read address is decoded and used to activate a specific row driver circuit (in row drive 330) to drive a word line within the memory array 350. As illustrated in FIG. 2B, activating a word line 210 turns on the port transistors 231 and 232 used to access the data in memory bit cell circuit 240. Referring back to FIGS. 3A and 4, after driving a specific word line in the SRAM array 350, the memory control circuitry 320 then instructs the read/write circuitry 360 to read data from a specific pair of bit lines during a sense data stage 440. As illustrated in FIG. 2B, the specific bit lines BL 220 and BL 225 are directed to a sense amplifier 299 within the read/write circuitry 360 to sense the state of the memory bit cell circuit 240. Referring to FIG. 4, at time point 441 at the end of the sense data stage 440, the requested data is available on the bit lines to be read out from the memory array 350. The data from the memory array will be provided to a buffer circuit 323 that drives a data out line 405 during a drive output stage 450. Thus, as illustrated in FIG. 4, the requested data is available during the drive output stage 450 during the second half of the memory cycle.

As illustrated in the timing diagram of FIG. 4, the time from when the read address is first presented to the memory system at the beginning of the clock cycle until the time 441 when the data is read from the SRAM array is much less than the entire memory clock cycle. Thus, it may seem desirable to shorten the clock cycle in order to improve the memory system performance. Specifically, one may wish to eliminate the much of the time after time point 441 until the end of the memory cycle. However, it is not easy to eliminate this time. For example, some data cells will take more time to read than other data cells due to their distance from the row drive 350 circuits and the read circuitry 360 such that the time period must encompass the worst-case situation. And more importantly, most of the extra time after the time point 441 when the data becomes available until the end of the memory clock cycle is required to perform some maintenance activities within the memory system to prepare the memory system for subsequent memory operations. The memory system maintenance activities will be described with reference to FIGS. 3B and 4.

Referring to FIG. 3B, the memory controller circuitry 320 may receive a request to read memory cell 353 in the memory array 350. As previously described with reference to FIG. 4, the memory controller circuitry 320 responds to the read request by proceeding through a predecode stage 410 and then a decode stage 430 in order to drive the word line associated with the row in the memory array 350 containing memory cell 353. Simultaneously, the memory controller circuitry 320 drives a word line for a “worst-case” reference cell 359 within the memory array 350. As illustrated in FIG. 3B, the worst-case reference cell 359 is located the entire memory array width 355 away from row drive circuits 330 and the entire memory array height 356 away from the read/write circuitry 360 such that worst-case reference cell 359 represents the longest possible signal line paths encountered within the memory array 350.

After row drive circuitry 330 drives the word line for the row containing the addressed memory cell 353, the memory controller circuitry 320 instructs the read/write circuitry 360 to read the associated bit lines for memory cell 353 during sense data stage 440. While reading the addressed memory cell 353, the read/write circuitry 360 also concurrently reads the worst-case reference cell 359 using sense amplifier 367. Since worst-case reference cell 359 has the longest signal path lines, sense amplifier 367 will complete reading worst-case reference cell 359 at a time 445 after any other data bit in the memory array 350 would have been ready to read. The completion of reading worst-case reference cell 359 is used to drive a completion signal 369 that signals the end of the read phase. The completion signal 369 causes the data bit that has been available since time 441 to be latched data buffer circuit 323 that is used to drive output data lines. A delayed version of the completion signal 369 is also provided to stop circuit 333 that turns off the activated word line drivers in row drive 330. The delayed version of the completion signal 369 may also be used to activate bit line precharge circuits within the read/write circuitry 360 to begin precharging the bit lines for the next memory cycle.

As is well-known in the field of digital memory circuits, bit line precharge circuits are used to precharge all of the bit lines within the memory array 350 before processing subsequent a memory access request. SRAM-based memory arrays precharge bit lines to an equalized positive voltage value before performing memory access operations. Bit line pre-charging increases the speed of read operations and allows memory bit cells to be very small. Specifically, the precharging of the memory array bit lines allows the very small transistors in the memory bit cell circuits to most quickly develop a voltage difference that will be detected by a differential sense amplifier. Thus, there must be an amount of time reserved during a memory cycle to precharge the bit lines within the memory array and allow precharged bit lines to settle before a memory read operation may be performed. (In the event of a write operation, the precharge can quickly be overwritten by write operation performed by the read/write circuitry 360.) As illustrated in the timing diagram of FIG. 4, the completion signal from reading the worst-case reference cell at time 445 may be used start a bit line precharge stage 461 after all of the word lines have been turned off The bit line precharging may occur simultaneously with the data output stage 450 since the read data bit is now represented in the data buffer circuit 323.

In order to reduce the memory cycle time, many memory systems have extended the bit line precharge stage that is normally at the end of a memory cycle into the beginning portion of the following memory cycle. Specifically, as illustrated in the timing diagram of FIG. 4, the bit line precharge operation may be extended into bit line precharge stage 462 that occurs concurrently with the predecode stage 410. However, the bit line precharge stage 462 must end before the decode & word line drive stage 430 begins since that stage will couple a row of memory cells to the bit lines through the port resistors 231 and 232. Thus, only a small amount of additional bit line precharge time 462 is available at the beginning of the memory cycle such that most of the precharging time 461 occurs at the end of the memory cycle.

8T Dual-Port SRAM

In many memory applications, it is desirable to allow two different entities to simultaneously access the same SRAM memory system independently. For example, in a multi-core processor system two different processing cores may wish to simultaneously read from the same memory cell in an array. To allow for this, a second physical port into a memory cell may be added to the memory cell.

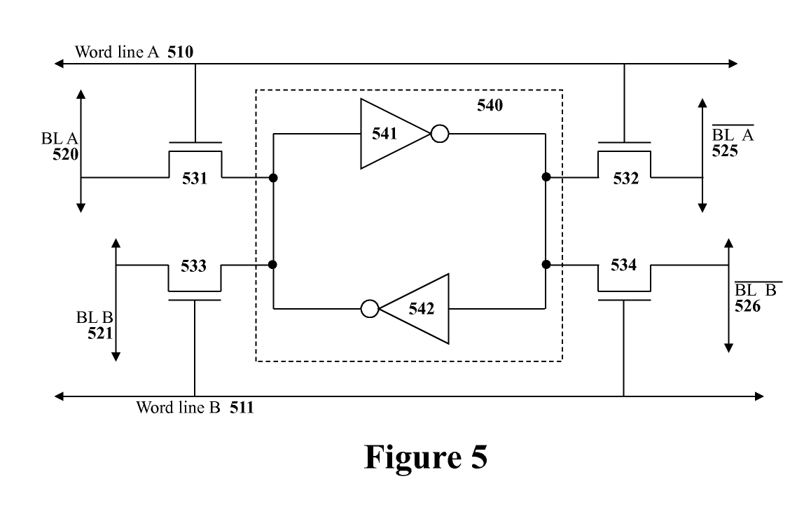

FIG. 5 illustrates an example of a typical dual-port SRAM bit cell. The dual-port SRAM cell of FIG. 5 is similar to the 6T SRAM bit cell of FIG. 2A except that in addition to the first pair of complementary port transistors 531 and 532, the dual-port memory cell of FIG. 5 also includes a second pair of complementary port transistors 533 and 534. The second pair of complementary port transistors 533 and 534 are controlled by second word line 511 (word line B) and have their own respective bit lines (data bit line B 521 and data bit line complement B 526). Since two transistors were added to the single port 6T SRAM cell circuit of FIG. 2A, the memory circuit of FIG. 5A is typically referred to as a dual-port 8T SRAM bit cell.

The addition of a second set of complementary port transistors, a second set of complementary bit lines, and an additional word line allows two independent memory using entities to access the contents of the 8T SRAM cell completely independently of each other. Specifically, the two different ports in the dual-port 8T SRAM cell of FIG. 5 operates in the same manner as illustrated in FIG. 4 such that two read operations may occur concurrently. However, the dual-port ability comes at the cost of increasing the size of the SRAM cell due to the additional area required to accommodate the additional complementary port transistors, the additional complementary bit lines, and the additional word line.

8T Alternating-Port SRAM

As set forth in the timing diagram of FIG. 4, a significant amount of the time (461 and 462) during a memory cycle must be spent precharging the bit lines to prepare for an incoming read operation. Some of the bit line precharging time 462 can overlap with the predecode stage 410 but most of the bit line precharging time 461 simply extends the amount of time before a subsequent memory operation can be processed. If it were possible to eliminate the bit line precharging time 461 then the memory clock cycle could be significantly shortened. The present disclosure proposes hiding the bit line precharging time 461 by using two different sets of bit lines and alternating memory operations using the two different sets of bit lines.

Referring again to FIG. 5, a typical eight transistor (8T) SRAM bit cell circuit has two different sets of bit lines: bit line pair A (520 and 525) and bit line pair B (521 and 526). In normal dual-port operation, the two different sets of bit lines are used concurrently and operating in the same data phases. To hide the necessary bit line precharge times, the present disclosure introduces a memory system wherein the two bit line pairs (and their associated support circuits) are used in an alternating pattern wherein one set of bit line pairs precharges while the other set of bit line pairs handles a memory operation. In the next memory cycle, the sets of bit line pairs exchange roles.

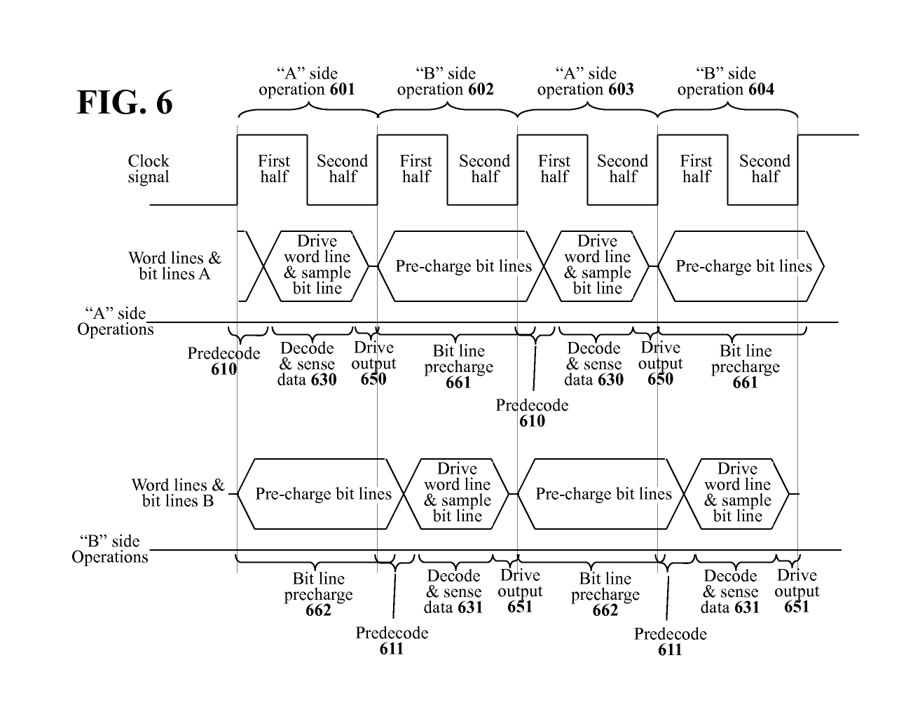

FIG. 6 illustrates a timing diagram of how the dual-port 8T SRAM bit cell circuit may be used to implement a high-speed single-port memory system by alternating access between the two ports. The top of FIG. 6 illustrates a clock signal wherein each memory clock cycle is divided into a first half and a second half. Each memory clock cycle is designated as an “A” side operation cycle (wherein the “A” bit line pair is being used to perform a memory operation) or a “B” side operation cycle (wherein the “B” bit line pair is being used to perform a memory operation). As illustrated in the area below the clock cycle, when the “A” bit line pair is used to perform a memory operation (in memory cycles 601 and 603) then the “B” bit line pairs are being precharged and when the “B” bit line pair is being used to perform a memory operation (in memory cycles 602 and 604) the “A” bit line pairs are being precharged. In this manner, the time spent precharging the bit lines for a subsequent memory operation can be hidden by alternating between the two pairs of bit lines.

The first memory cycle depicted in FIG. 6 is an “A” side memory operation 601. At the beginning of an “A” side memory operation 601, the memory control circuitry receives a memory address as part of a memory access request and processes that memory address in a predecode stage 610. Note that during this predecode stage 610 the “A” bit lines may still be in a precharging state.

After the predecode stage 610, the memory controller then decodes the address, drives the “A” word line 510 for the appropriate row in the memory array during decode and sense data stage 630. Next, the memory controller instructs the read/write circuitry to sense the requested data bit on the appropriate pair of “A” bit lines (520 and 525). When the requested data bit has been read out of the memory array, the data bit is output during a drive output stage 650. The drive output stage 650 can be short since the entity that requested the memory read operation may just latch the data bit using the rising edge of the next memory clock cycle.

During the bit line “A” memory operation cycle 601, all of the “B” bit lines in the memory array are precharged during precharge stage 662. Thus, referring to FIG. 5, while the “B” bit lines 521 and 526 are being precharged during operation cycle 601. The precharged “B” bit lines 521 and 526 have absolutely no effect on the memory bit cell 540 since the “B” word line 511 is not being asserted thus the “B” port transistors 533 and 534 isolate the “B” bit lines 521 and 526 from the memory bit cell 540.

Referring back to FIG. 6, once the “A” side operation cycle 601 ends then a “B” side operation cycle 602 begins wherein the roles are reversed for the “A” and “B” ports. At the start of the “B” side operation cycle 602 the memory control system receives a memory address in the memory access request and processes that memory address in a predecode stage 611. Next, the memory controller decodes the memory address, drives a “B” word line 511, and senses the requested data bit on the appropriate pair of “B bit lines (521 and 526) during decode and sense data stage 631. Finally, the data bit read from the memory array is output during drive output stage 651 at the end of “B” side operation 602. During this entire “B” side memory cycle 602, all of the “A” bit lines are precharged during bit line precharge stage 661.

The “A” and “B” ports of the memory cell are accessed in this alternating manner such that the time required to precharge bit lines is effectively hidden from the memory cycle since the precharging occurs concurrently with another memory operation. By hiding the normal precharge stage 461 of FIG. 4 that is required in traditional SRAM systems, the alternating “A” and “B” port system can reduce the memory cycle by 20 to 30%.

It should be noted that although the teachings can be used with a standard 8T dual-port SRAM cell layout that is available in many existing circuit libraries, the system of the present invention can be implemented with a more compact version of an 8T dual-port SRAM cell layout. With the standard 8T dual-port SRAM cell layout that is currently used as a dual-port memory bit cell, the transistors of the memory bit cell must be sized in specific proportions that prevent a data value from being lost during read operations. Specifically, if two different entities attempt to read the same 8T dual-port SRAM bit cell at the same time, then the precharge on the bit lines could accidentally destroy the data bit currently stored in the memory bit cell. Thus, in a standard 8T dual-port SRAM cell layout certain transistors are manufactured with a large size to prevent this data corruption from occurring when two simultaneous read operations access the same memory bit cell. However, with the alternating port system disclosed in this document, the same memory bit cell is never read by the two data ports concurrently. Only one port will ever be activated at a time since the other port will be turned off while the bit lines are precharged. Thus, a smaller 8T dual-port SRAM cell layout may be used to implement the 8T dual-port SRAM cell for use in the alternating port system disclosed herein.

6T Alternating-Port SRAM System

A traditional dual-port SRAM bit cell uses two different physical pairs of port transistors as illustrated in the eight-transistor (8T) SRAM bit cell of FIG. 5. However, there are several other types of dual-port memory bit cell designs. As long as a dual-port memory bit cell design has bit lines that are physically distinct from each other such that one may be used in a memory operation while the other is precharged, the alternating port system of the present disclosure may be employed with that dual-port memory bit cell to reduce the overall memory cycle time.

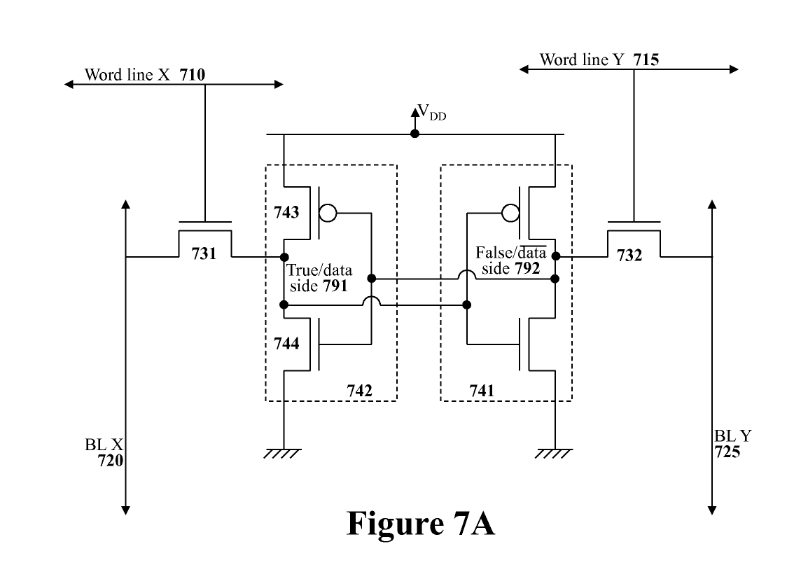

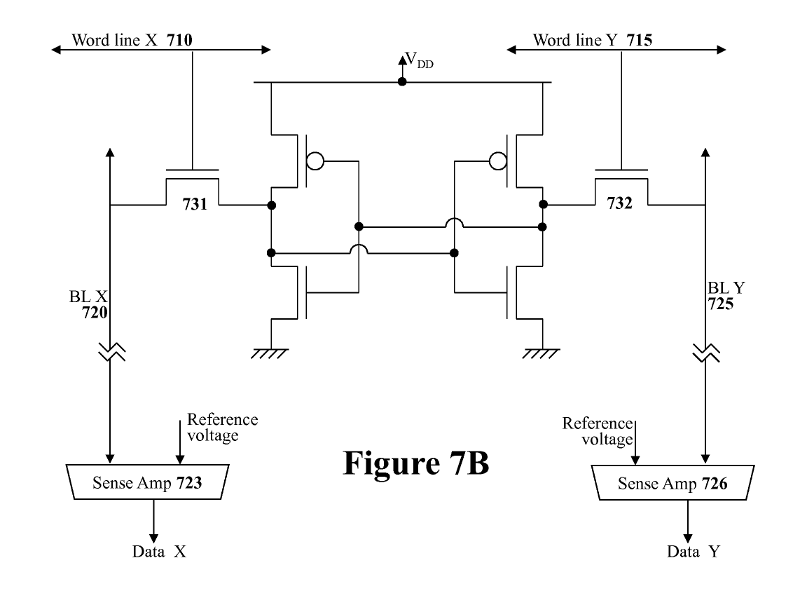

As set forth with reference to FIG. 2B, a read operation into a 6T SRAM bit cell is generally performed by activating word line 210 that couples both sides (291 and 292) of the memory bit cell 240 concurrently to a differential sense amplifier 299 using a pair of complementary bit lines BL 220 and B̅L̅ 225. However, it is possible to read the data state from the 6T memory bit cell of FIGS. 2A to 2C by only reading from one side of the memory bit cell 240. FIG. 7A illustrates one embodiment of a 6T SRAM bit cell that can be read using a single-ended bit line.

FIG. 7A illustrates a 6T dual-port memory bit cell that has two independently controllable word lines (word line X 710 and word line Y 715) that each control associated port transistors (731 and 732) located on opposite sides of the memory cell. Specifically, word line X 710 controls port transistor 731 that accesses the true side 791 and word line Y 715 controls port transistor 732 that accesses the false side 792. Note that each row of a memory array constructed with the 6T dual-port cell of FIG. 7A has both an X word line 710 and Y word line 715 that each independently control one of the two bit lines (bit line X 720 and bit line Y 725, respectively). To perform a single-ended read operations into the 6T memory bit cell of FIG. 7A, either word line X 710 or word line Y 715 is activated to read data out from the memory bit cell.

The individually controllable ports on each end the 6T dual-port memory bit cell of FIG. 7A may be used in the alternating bit line system of the present disclosure that hides bit line precharge times. Specifically, word line X 710 is asserted in one row for a first read operation from the data/true side 791 using bit line X 720 during a first memory cycle. Simultaneously, the separate bit line Y 725 (and all the other Y bit lines in the array) can be precharged during that first memory cycle since word line Y 715 will not be activated. Then, in the following memory cycle, word line Y 715 may be asserted (in any row of the same memory array) for a read operation using bit line Y 725 that was precharged in the previous memory cycle. Bit line X 720 (and all the other X bit lines in the array) may be precharged during that following memory cycle while bit line Y 725 is used to perform a memory operation. Note that the memory operation performed using word line Y 715 and bit line Y 725 will be access the data-complement/false side 792 of the memory bit cell such that the data bit must be inverted.

The physical construction of the 6T dual-port memory cell of FIG. 7A is very similar to the traditional single port 6T SRAM cell of FIGS. 2A to 2C except that the memory cell of FIG. 7A requires two independent word lines (word line X 710 and word line Y 715) routed to each SRAM bit cell. This can be managed by using the standard techniques for routing the two word lines used in the dual-port 8T SRAM cell of FIG. 5 with the smaller single port 6T SRAM cell of FIGS. 2A to 2C. The resulting 6T dual-port memory cell of FIG. 7A will be significantly smaller than the dual-port 8T SRAM cell of FIG. 5 since there is only one port transistor on each side of the memory cell.

The single-ended read operation from the 6T dual-port memory bit cell of FIG. 7A may be performed as a “pseudo-differential read operation” that compares the signal from the memory cell with a reference voltage. FIG. 7B illustrates an arrangement for performing a pseudo-differential read operation. In FIG. 7B each bit line is coupled to a sense amplifier that also has a synthetically generated voltage reference value as an input. The synthetically generated voltage reference value is somewhere between the voltage value for a logical “1” and the voltage value for a logical “0”. During a pseudo-differential read operation, the output of a bit line (720 or 725) is compared against the synthetically generated reference voltage value to output a data value (Data X or Data Y). Additional detailed information on using the 6T dual-port memory bit cell of FIGS. 7A and 7B can be obtained from the U.S. patent application entitled “Methods and Apparatus for Designing and Constructing Multi-port Memory Circuits with Voltage Assist” filed on Mar. 15, 2012 having Ser. No. 13/421,704 which is hereby incorporated by reference in its entirety.

The 8T dual-port memory cell of FIG. 5 and the 6T dual-port memory cell of FIGS. 7A and 7B illustrate two memory bit cell designs that may use the alternating bit line teachings of the present disclosure. However, many other types of memory cell circuits can use the teachings of the present disclosure. Specifically, as long as memory cell design has physically distinct sets of bit lines such that the different sets of bit lines can be precharged independently of each other, the alternating port system of the present disclosure may be employed to reduce the overall memory cycle time by eliminating the precharge time from the critical path of a memory read operation since the precharge is performed in parallel with another memory operation.

The preceding technical disclosure is intended to be illustrative, and not restrictive. For example, the above-described embodiments (or one or more aspects thereof) may be used in combination with each other. Other embodiments will be apparent to those of skill in the art upon reviewing the above description. The scope of the claims should, therefore, be determined with reference to the appended claims, along with the full scope of equivalents to which such claims are entitled. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim is still deemed to fall within the scope of that claim. Moreover, in the following claims, the terms “first,” “second,” and “third,” etc. are used merely as labels, and are not intended to impose numerical requirements on their objects.

The Abstract is provided to comply with 37 C.F.R. §1.72(b), which requires that it allow the reader to quickly ascertain the nature of the technical disclosure. The abstract is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment.

We claim:

1. A high-speed digital memory system for storing data bits, said high-speed digital memory system comprising:
a plurality of memory cells, each of said plurality of memory cells storing a bit of data;
a first set of bit lines coupled to said plurality of memory cells for accessing said bit of data stored in said plurality of memory cells, said first set of bit lines coupled to said plurality of memory cells using a first set of word lines;
a second set of bit lines coupled to said plurality of memory cells for accessing said bit of data stored in said plurality of memory cells, said second set of bit lines coupled to said plurality of memory cells using a second set of word lines; and
a memory control system, said memory control system accessing a first target memory cell in said plurality of memory cells using said first set of bit lines while precharging said second set of bit lines during a first memory cycle, said memory control system accessing a second target memory cell in said plurality of memory cells using said second set of bit lines while precharging said first set of bit lines during a second memory cycle following said first memory cycle.

2. The high-speed digital memory system as set forth in claim 1 wherein said first set of bit lines comprises a set of bit line pairs wherein each bit line pair comprises a bit line and a complementary bit line.

3. The high-speed digital memory system as set forth in claim 2 wherein each of said plurality of memory cells comprises an eight-transistor SRAM cell.

4. The high-speed digital memory system as set forth in claim 1 wherein said first set of bit lines comprises a first set of single-ended bit lines coupled to a first side of said plurality of memory cells and said second set of bit lines comprises a second set of single-ended bit lines coupled to a second complementary side of said plurality of memory cells.

5. The high-speed digital memory system as set forth in claim 4 wherein each of said plurality of memory cells comprises a six-transistor SRAM cell.

6. The high-speed digital memory system as set forth in claim 1, said high-speed digital memory system further comprising:
a data buffer circuit for storing a data bit read from said plurality of memory cells.

7. The high-speed digital memory system as set forth in claim 4 wherein said memory control system reads from a worst case reference cell to determine when to stop driving word lines.

8. A method for accessing data bits in a digital memory system comprising a plurality of memory cells, said method comprising:
accessing a first target memory cell in said plurality of memory cells using a first set of bit lines coupled to said plurality of memory cells during a first memory cycle;
precharging a second set of bit lines coupled to said plurality of memory cells during said first memory cycle;
accessing a second target memory cell in said plurality of memory cells using said second set of bit lines during a second memory cycle following said first memory cycle; and
precharging said first set of bit lines coupled to said plurality of memory cells during said second memory cycle.

9. The method for accessing data bits in a digital memory system as set forth in claim 8 wherein said first set of bit lines comprises a set of bit line pairs wherein each bit line pair comprises a bit line and a complementary bit line.

10. The method for accessing data bits in a digital memory system as set forth in claim 9 wherein each of said plurality of memory cells comprises an eight-transistor SRAM cell.

11. The method for accessing data bits in a digital memory system as set forth in claim 8 wherein said first set of bit lines comprises a first set of single-ended bit lines coupled to a first side of said plurality of memory cells and said second set of bit lines comprises a second set of single-ended bit lines coupled to a second complementary side of said plurality of memory cells.

12. The method for accessing data bits in a digital memory system as set forth in claim 11 wherein each of said plurality of memory cells comprises a six-transistor SRAM cell.

13. The method for accessing data bits in a digital memory system as set forth in claim 8, said method further comprising:
storing a data bit read from said plurality of memory cells into a data buffer circuit.

14. The method for accessing data bits in a digital memory system as set forth in claim 8, said method further comprising:
reading a worst case reference cell to determine when a read operation has completed; and
turning off word lines after reading said worst case reference cell.
